(19) United States
(12) Patent Application Publication
(10) Pub. No.: US 2026/0048421 A1
(43) Pub. Date: Feb. 19, 2026

(54) SUBSTRATE TREATMENT APPARATUS HAVING HEATING UNIT

(71) Applicant: DEVICE CO., LTD., Chungcheongnam-do (KR)

(72) Inventor: Taek Youb Lee, Cheonan-si (KR)

(73) Assignee: DEVICE CO., LTD., Chungcheongnam-do (KR)

(21) Appl. No.: 19/000,306

(22) Filed: Dec. 23, 2024

(30) Foreign Application Priority Data
Aug. 14, 2024 (KR) 1020240109013

(51) Int. Cl. B08B 3/10; B08B 13/00; G01N 21/59; G01N 21/88; H01L 21/67

(52) U.S. Cl. CPC B08B 3/10; B08B 13/00; G01N 21/59; G01N 21/8806; H01L 21/67051

(57) ABSTRACT

The present disclosure relates to a substrate treatment apparatus including: a substrate-holding unit for holding and rotating a substrate; a treatment liquid feed unit for feeding treatment liquid to a top or underside of the substrate; a heating unit located under the substrate to heat the substrate; a blocking plate located on the substrate-holding unit above the heating unit; upper sensors located above the blocking plate to constitute one of a light transmitter and a light receiver; and lower sensors located under the blocking plate to constitute the other, wherein a quantity of light irradiated from the light transmitter and thus reaching the light receiver is measured to allow the light transmittance of the blocking plate to be obtained.

### CROSS REFERENCE TO RELATED APPLICATION OF THE DISCLOSURE

The present application claims the benefit of Korean Patent Application No. 10-2024-0109013 filed in the Korean Intellectual Property Office on Aug. 14, 2024, the entire contents of which are incorporated herein by reference.

### FIELD OF THE DISCLOSURE

The present disclosure relates to a substrate treatment apparatus having a heating unit, more specifically to a substrate treatment apparatus having a heating unit that is capable of being configured to measure light transmittance of a blocking plate through which radiation heat of the heating unit passes.

### BACKGROUND OF THE RELATED ART

Generally, a substrate treatment apparatus is an apparatus that performs, with the use of treatment liquids, various processes such as deposition, photolithography, etching, and cleaning for substrates such as semiconductor wafers, display substrates, optical disk substrates, magnetic disk substrates, photomask substrates, ceramic substrates, solar cell substrates, and the like.

Among them, the cleaning is carried out to remove foreign substances or particles from the substrate, and representatively, the cleaning includes a process of feeding treatment liquid to top or underside of the substrate, while the substrate is rotating at a high speed in a state of being supportedly placed on top of a chuck base (spin head).

In this case, a heating unit such as LEDs or a laser beam irradiation device is located under the substrate to allow the substrate to be heated to a given temperature, and next, if the heated substrate rotates so that it is subjected to a given treatment, a reaction occurs fast to reduce the amount of treatment liquid used. Further, the environmental contamination caused by the treatment liquid used is minimized, and the time required for the treatment is shortened to achieve improvement of productivity and a reduction in the quantity of electricity consumed.

FIG. 1 is a sectional view showing a conventional substrate treatment apparatus having a heating unit, and a configuration of the conventional substrate treatment apparatus will be briefly described below.

The substrate treatment apparatus includes a chuck base 1 having chuck pins 5 located on top thereof, a heating unit 3 located under the substrate W to heat a substrate W rotating, a treatment liquid feed unit 7 located above the substrate W fixed to the chuck pins 5 to spray a treatment liquid onto top of the substrate W, and a back nozzle assembly 2 located on the underside of a center of the substrate W in such a way as to pass through the chuck base 1 to spray the treatment liquid onto the underside of the substrate W.

Further, the substrate treatment apparatus includes a blocking plate 4 made of quartz and located between the heating unit 3 and the substrate W in such a way as to prevent the treatment liquid sprayed from the treatment liquid feed unit 7 or the back nozzle assembly 2 from entering the heating unit 3 and thus causing a short circuit and to allow the radiation heat of the heating unit 3 to be transferred smoothly to the substrate W.

Furthermore, hydrofluoric acid is used for various purposes such as for etching the substrate W, and the hydrofluoric acid has the properties of corrosion (melt) for quartz. As the corrosion of the quartz is developed, the light transmittance of radiation heat has a tendency to decrease.

If the hydrofluoric acid is sprayed onto the top of the substrate W from the treatment liquid feed unit 7, a relatively small region of the blocking plate 4 is exposed to the hydrofluoric acid because of the existence of the substrate W, so that an amount of the blocking plate 4 corroded becomes reduced. However, if the hydrofluoric acid is sprayed onto the underside of the substrate W from the back nozzle assembly 2, it rebounds from the underside of the substrate W and a bowl assembly 8 located around the substrate W, a lot of mist and fume are generated to cause the corrosion to occur more quickly and seriously.

FIG. 2 is a graph showing substrate temperatures according to the outputs of the heating unit 3 in cases where light transmittance of a light transmitting member constituting the blocking plate 4 is 88% and 94%, and FIG. 3 is a graph showing light transmittance of the light transmitting members exposed to low and high density hydrofluoric acids according to time.

As shown, in the case where the light transmittance is 88%, the temperature of the substrate W is substantially lower than that in the case where the light transmittance is 94%, and in the case where the light transmitting member is exposed to high density hydrofluoric acid, the light transmittance becomes substantially lower than that in the case where the light transmitting member is exposed to low density hydrofluoric acid, as time passes.

If the light transmittance decreases, the temperature of the substrate W is not raised up to a target temperature, which fails to accomplish given objects of the heating unit 3. Therefore, it is desirable that the light transmittance of the blocking plate 4 be kept greater than or equal to 90%, and if such light transmittance is not obtained, there is a need to replace the blocking plate 4 with new one.

However, the blocking plate 4 is built on the existing substrate treatment apparatus, and to measure the light transmittance of the blocking plate 4 exposed to the hydrofluoric acid, therefore, the blocking plate 4 is separated from the substrate treatment apparatus and located at a separate place, so that the time required for the detachment and attachment of the blocking plate 4 becomes long, thereby causing low productivity.

To solve such a problem, the blocking plate 4 is periodically replaced with new one according to the use time of the substrate treatment apparatus, but in this case, even a still good blocking plate 4 may be replaced with new one, which disadvantageously causes the waste of the high-priced blocking plate 4. If a bad blocking plate 4 is kept used, without any replacement at an appropriate time point, it is replaced with new one after defects have occurred on a plurality of substrates W, which has many influences on yield to cause low productivity.

### SUMMARY OF THE DISCLOSURE

Accordingly, the present disclosure has been made in view of the above-mentioned problems occurring in the related art, and it is an object of the present disclosure to provide a substrate treatment apparatus having a heating unit that is capable of allowing equipment for measuring light transmittance of a blocking plate to be located thereon, so that there is no need to measure the light transmittance of the blocking plate at a separate place in the state where the blocking plate is separated therefrom, thereby keeping high productivity.

To accomplish the above-mentioned objects, according to the present disclosure, there is provided a substrate treatment apparatus including: a substrate-holding unit for holding and rotating a substrate; a treatment liquid feed unit for feeding treatment liquid to a top or underside of the substrate held by the substrate-holding unit; a heating unit located under the substrate to heat the substrate; a blocking plate located on the substrate-holding unit above the heating unit in such a way as to allow light to pass therethrough toward the substrate and to prevent the treatment liquid from entering the heating unit; an upper sensor located above the blocking plate to constitute one of a light transmitter and a light receiver; and a lower sensor located under the blocking plate to constitute the other, wherein a quantity of light irradiated from the light transmitter and thus reaching the light receiver is measured to allow the light transmittance of the blocking plate to be obtained.

According to the present disclosure, desirably, the upper sensor and the lower sensor may be connected to light production and measurement devices through optical fibers, and the light production and measurement devices may be connected to a controller.

According to the present disclosure, desirably, two or more sets of the upper sensor and the lower sensor may be provided at different positions in a radial direction of the substrate about the center of the substrate.

According to the present disclosure, desirably, the upper sensor and the lower sensor may have respective light collection lenses.

According to the present disclosure, desirably, a light source applied to the light transmitter may be an LED or laser light.

According to the present disclosure, desirably, the light transmittance at various points on a concentric circle of the blocking plate may be measured through the rotation of the substrate-holding unit.

According to the present disclosure, desirably, the lower sensor may be located under the substrate-holding unit, and the substrate-holding unit and the heating unit may have first light passing hole and second light passing hole formed thereon to allow the light irradiated from the light transmitter to pass therethrough respectively.

According to the present disclosure, desirably, in plan view, the first light passing hole formed on the substrate-holding unit has a shape of arc about the center of the substrate and includs the position of the lower sensor.

According to the present disclosure, desirably, the upper sensor and the lower sensor may reciprocate in a radial direction about a center of the substrate, and the first light passing hole and the second light passing hole extend in the radial direction respectively.

According to the present disclosure, desirably, the first light passing hole further extends in an circular direction about the center of the substrate so that the first light passing hole has crossing shape in the radial direction and circular direction.

### BRIEF DESCRIPTION OF THE DRAWINGS

The above and other objects, features and advantages of the present disclosure will be apparent from the following detailed description of the embodiments of the disclosure in conjunction with the accompanying drawings, in which:

FIG. 1 is a longitudinal sectional view showing a conventional substrate treatment apparatus having a heating unit;

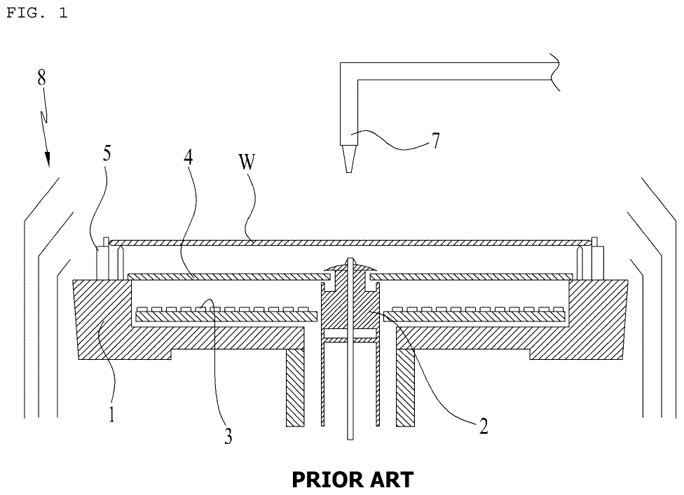

FIG. 2 is a graph showing substrate temperatures according to the outputs of a heating unit in cases where light transmittance of a light transmitting member is 88% and 94% respectively;

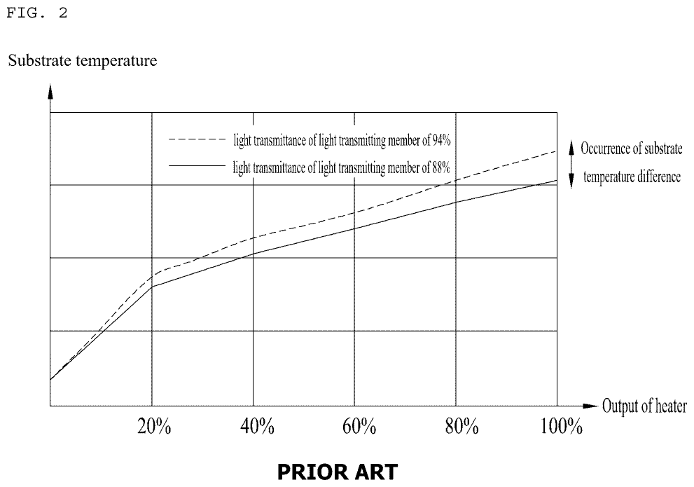

FIG. 3 is a graph showing light transmittance of the light transmitting members exposed to low and high density hydrofluoric acids according to time respectively;

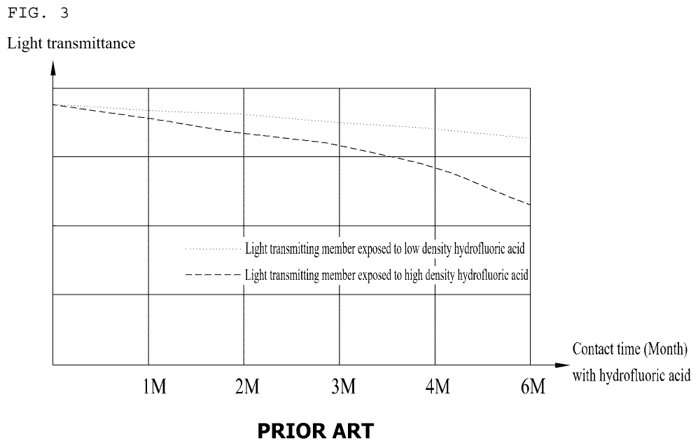

FIG. 4 is a longitudinal sectional view showing a substrate treatment apparatus according to a first embodiment of the present disclosure;

FIG. 5 is a plan view showing the substrate treatment apparatus according to the first embodiment of the present disclosure;

FIG. 6 is a longitudinal sectional view showing a substrate treatment apparatus according to a second embodiment of the present disclosure;

FIG. 7 is a plan view showing the substrate treatment apparatus according to the second embodiment of the present disclosure; and

FIG. 8 is a plan view showing a range where light transmittance is measurable in a substrate treatment apparatus according to a third embodiment of the present disclosure.

### DETAILED DESCRIPTION OF THE PREFERRED EMBODIMENT

Hereinafter, an embodiment of the present disclosure will be explained in detail with reference to the attached drawings.

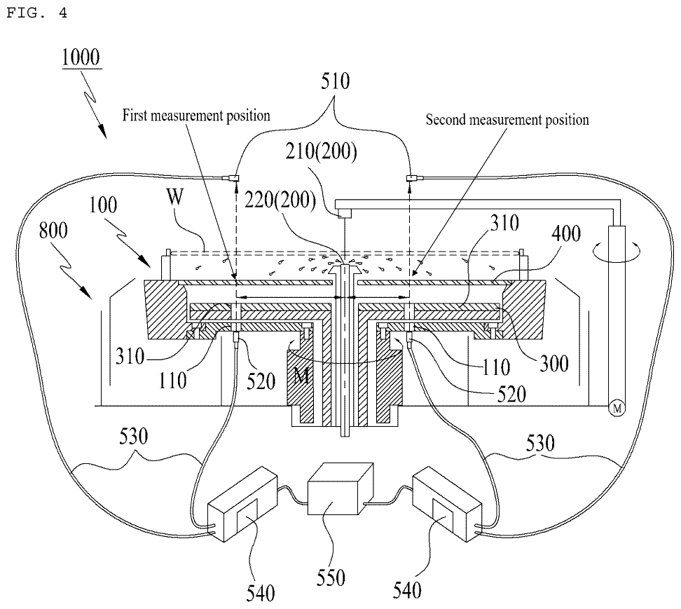

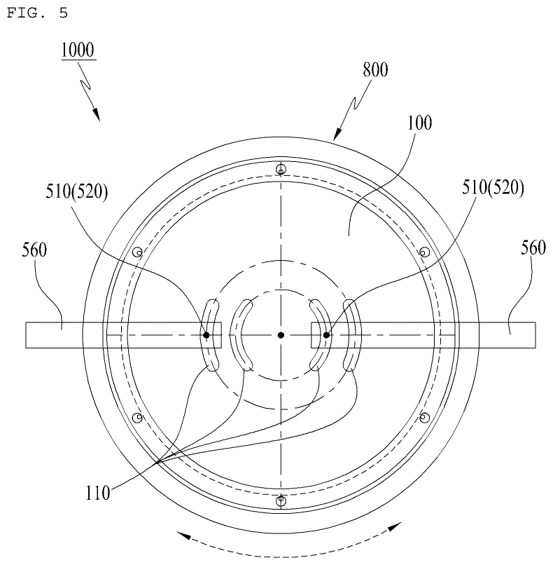

As shown in FIGS. 4 and 5, a substrate treatment apparatus 1000 according to a first embodiment of the present disclosure includes: a substrate-holding unit 100 for holding and rotating a substrate W; a treatment liquid feed unit 200 for feeding treatment liquid 210 to a top or underside of the substrate W held by the substrate-holding unit 100; a heating unit 300 located under the substrate W to heat the substrate W; a blocking plate 400 located on the substrate-holding unit 100 above the heating unit 300 in such a way as to allow light to pass therethrough toward the substrate W and to prevent the treatment liquid from entering the heating unit 300; upper sensors 510 located above the blocking plate 400 to constitute one of a light transmitter and a light receiver; and lower sensors 520 located under the blocking plate 400 to constitute the other.

In this case, the blocking plate 400 is located on the substrate-holding unit 100 and rotatable, together with the substrate-holding unit 100, and the substrate-holding unit 100 is rotatable by a driving motor M.

The heating unit 300 is provided as a non-rotary body, and otherwise, it may be rotatable in the range of a given angle. Even though the heating unit 300 is rotatable, it does not rotate, together with the substrate-holding unit 100.

The upper sensors 510 and the lower sensors 520 are located on sensor support rods 560.

In the figures, the upper sensors 510 and the lower sensors 520 are shown as being provided in two respectively, but it is also possible to install only one.

Under such a configuration, a quantity of light irradiated from the light transmitter and thus reaching the light receiver is measured to allow the light transmittance of the blocking plate 400 to be obtained.

As shown in FIG. 4, the upper sensors 510 and the lower sensors 520 are connected to light production and measurement devices 540 through optical fibers 530, and the light production and measurement devices 540 are connected to a controller 550.

The light production and measurement devices 540 serve to produce and amplify light, transmit the amplified light to the light transmitter, and measure the quantity of light returned from the light receiver for receiving the irradiated light from the light transmitter.

The quantity of light produced from the light production and measurement device 540 is predetermined (pre-measured) and transmitted to the light transmitter through the optical fibers 530, and the light irradiated from the light transmitter passes through the blocking plate 400 and reaches the light receiver. After that, the quantity of light is sensed through the light receiver, returned from the light receiver through the optical fibers 530, and finally measured by means of the light production and measurement devices 540.

The controller 550 calculates light transmittance from the quantity of light of the light transmitter and the quantity of light sensed through the light receiver.

The controller 550 is connected to a display device or computer to allow the calculated light transmittance to be checked with the naked eye.

According to the present disclosure, the substrate treatment apparatus 1000 has the blocking plate 400 located thereon, but the light transmittance of the blocking plate 400 is measured at an arbitrary time point, without any separation of the blocking plate 400, thereby advantageously keeping high productivity.

As shown in FIGS. 4 and 5, two or more sets of the upper sensors 510 and the lower sensors 520 are provided at different positions (first and second measurement positions) in a radial direction of the substrate W about the center of the substrate W.

Under such a configuration, the light transmittance is measured on such different positions in the radial direction of the substrate 3 respectively, thereby allowing the replacement time point of the blocking plate 400 to be made more accurately.

If the plurality of sets of the upper sensors 510 and the lower sensors 520 perform their measurement at the plurality of positions, the determination for the replacement time point of the blocking plate 400 depends on whether an average value of the light transmittance of the plurality of positions reaches a given set value or whether the light transmittance of the individual positions reaches the given set value.

Further, the upper sensors 510 and the lower sensors 520 desirably have respective light collection lenses (not shown) adapted to measure the light transmittance more accurately. In this case, the lenses are located on the front end of the light transmitter and the rear end of the light receiver.

Further, the light source applied to the light transmitter is an LED or laser light.

The light transmittance on at various points on a concentric circle of the blocking plate 400 can be measured through the rotation of the substrate-holding unit 100.

After the light transmittance has been measured on any one position, if the light transmittance is measured in the state where the substrate-holding unit 100 and the blocking plate 400 rotate by a given angle, it can be measured at a plurality of positions on a concentric region or circle.

This is possible when the lower sensors 520 are located between the heating unit 300 and the bottom of the substrate-holding unit 100.

However, if such a configuration is hard due to interferences of peripheral parts such as data lines or power lines, the lower sensors 520 are located under the substrate-holding unit 100, and further, the substrate-holding unit 100 and the heating unit 300 have first light passing hole 110 and second light passing hole 310 formed thereon to allow the light irradiated from the light transmitter to pass therethrough respectively.

Under such a configuration, the upper sensors 510 are located above a position where the substrate W is located and the lower sensors 520 are located under the substrate-holding unit 100, so that the upper sensors 510 and the lower sensors 520 are built more easily, and the light irradiated from the light transmitter passes through the first light passing hole 110 and the second light passing hole 310 sequentially, passes through the blocking plate 400, and finally reaches the light receiver smoothly.

Of course, in the case where the light transmitter and the light receiver are located on the opposite positions to each other, the light irradiated from the light transmitter passes through the blocking plate 400, passes through the second light passing hole 310 and the first light passing hole 110 sequentially, and finally reaches the light receiver.

As shown in FIG. 5, in plan view, the first light passing hole 110 formed on the substrate-holding unit 100 has a shape of arc about the center of the substrate and includes the position of the lower sensor 520.

Therefore, in the state where the substrate-holding unit 100 rotates by a given angle, the light transmittance on different concentric points of the blocking plate 400 is measurable.

As shown, the plurality of arc-shaped first light passing hole 110 can be formed on the concentric circles about the center of the substrate W.

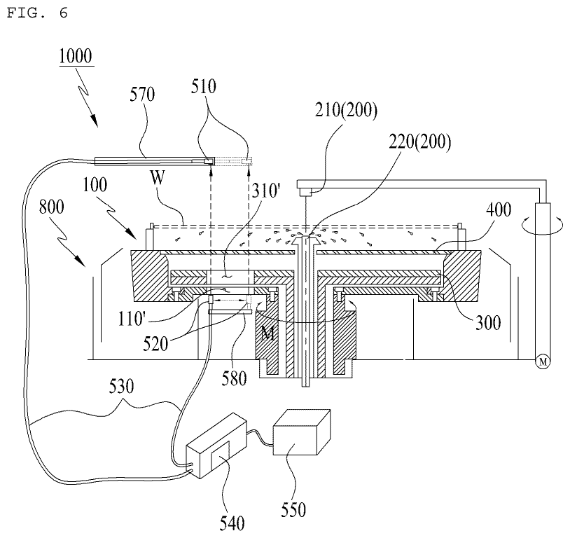

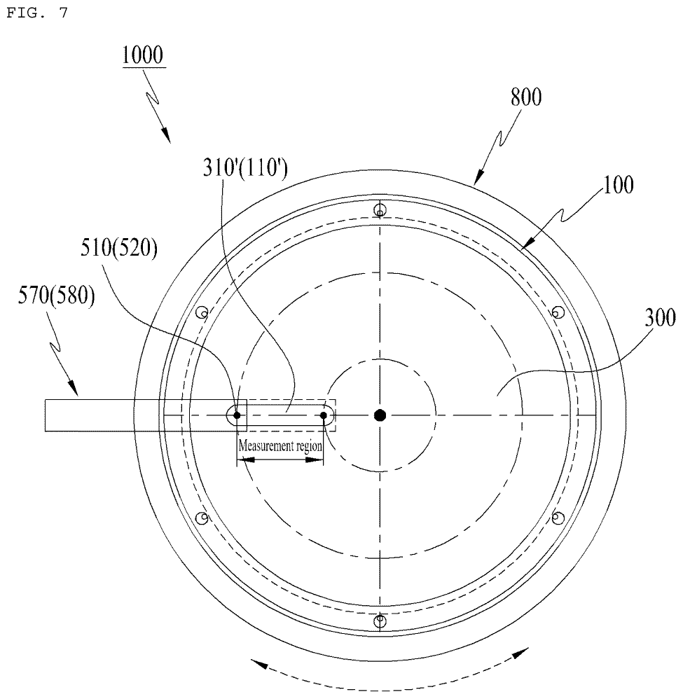

As shown in FIGS. 6 and 7, further, the upper sensors 510 and the lower sensors 520 are installed to be able to reciprocate from a center of the substrate W in a radial direction of the substrate W, and first light passing hole 110′ and second light passing hole 310′ are formed on the bottom of substrate-holding unit 100 and the heating unit 300 in such a way as to extend in the radial direction of the substrate W.

Under such a configuration, if the upper sensors 510 and the lower sensors 520 move by given distances from the center of the substrate 3 in the radial direction of the substrate W in the state where they are located at the corresponding positions to each other, the light transmittance of the blocking plate 400 is measured at different positions in the radial direction of the blocking plate 400.

The upper sensors 510 and the lower sensors 520 can be built on expandable sensor support rods 570 and 580 in such a way as to be movable in the radial direction of the substrate W.

The expandable sensor support rods 570 and 580 are constituted of feed screws or LM guides that are driven by a pressure type cylinder or motor, and of course, other known parts may be provided as the expandable sensor support rods 570 and 580.

In the drawings, one set of expandable sensor support rods 570 and 580 is provided, but a plurality of sets may be provided spaced apart from one another about the center of the substrate W in a circumferential direction of the substate W.

Additionally, the first light passing hole 110 including the positions of the lower sensors 520 are formed on the bottom of the substrate-holding unit 100 in such a way as to extend to the shape of arc about the center of the substrate W, so that in the state where the substrate-holding unit 100 rotates by a given angle, the light transmittance of the blocking plate 400 can be measured at various points on a concentric circle about the center of substrate W on the blocking plate 400.

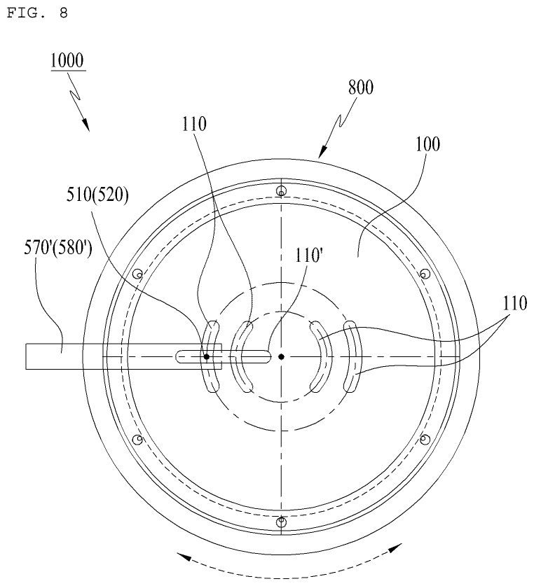

In detail, as shown in FIG. 8, the upper sensors 510 and the lower sensors 520 are built on expandable sensor support rods 570′ and 580′ in such a way as to be movable in the radial direction of the substrate W, so that the light transmittance of the blocking plate 400 is measurable through the first light passing hole 110′ and the second light passing hole 310′ formed on the substrate-holding unit 100 and the heating unit 300 in such a way as to extend in the radial direction of the substrate W. Simultaneously, the arc-shaped first light passing hole 110 including the positions of the lower sensors 520 are formed about the center of the substrate W, so that the light transmittance of the blocking plate 400 is measured at multiple locations on a concentric circle of the blocking plate 400.

In this case, desirably, the measurable regions by the upper sensors 510 and the lower sensors 520 are defined by the radially extending first light passing hole 110′ and the arc-shaped first light passing hole 110 crossing the radially extending first light passing hole 110′, and therefore, the radially extending first light passing hole 110′ and the arc-shaped first light passing hole 110 form the measurement range of the light transmittance.

In the drawings, one set of expandable sensor support rods 570′ and 580′ is provided, but a plurality of sets may be provided spaced apart from one another about the center of the substrate W in the circumferential direction of the substate W.

In addition, as shown in the drawing, the arc-shaped first light passing hole 110 can be formed at two or more different locations along the radial direction with respect to the center of the substrate W.

According to the present disclosure, under such a configuration, the substrate treatment apparatus 1000 has the sensors 510 and 520 located thereon, so that there is no need to measure the light transmittance of the blocking plate 400 at a separate place in the state where the blocking plate 400 is separated therefrom, thereby advantageously keeping high productivity.

According to the present disclosure, further, the light transmittance is measurable at the different positions on a concentric circle about the center of the substrate W and at the different positions in the radial direction of the substrate W about the center of the substrate W.

If the light transmittance is measured at the plurality of positions of the blocking plate 400, the replacement time point of the blocking plate 400 is determined according to a user's reference. For example, the replacement time point of the blocking plate 400 depends on whether an average value of the light transmittance of the plurality of positions reaches a given set value or whether the light transmittance of the individual positions reaches the given set value.

Further, the measurement of the light transmittance is carried out periodically according to time or the number of substrates W treated.

A reference numeral 800 not explained yet represents a bowl assembly for receiving the treatment liquid for the substrate W.

As described above, the substrate treatment apparatus according to the present disclosure is configured to have the upper sensors located above the blocking plate to constitute one of the light transmitter and the light receiver and the lower sensors located under the blocking plate to constitute the other, so that a quantity of light irradiated from the light transmitter and thus reaching the light receiver is measured to allow the light transmittance of the blocking plate to be obtained, thereby the sensors for measuring light transmittance being installed together with the substrate treatment apparatus and having no need to measure the light transmittance of the blocking plate at a separate place, in the state where the blocking plate is separated from the substrate treatment apparatus, to thus keep high productivity.

Further, the substrate treatment apparatus according to the present disclosure is configured to allow two or more sets of the upper sensors and the lower sensors to be located at different positions in the radial direction of the substrate about the center of the substrate, so that light transmittance is measured at the different positions in the radial direction of the substrate, respectively, thereby enabling the determination for the replacement time point of the blocking plate to be more accurately made.

Furthermore, the substrate treatment apparatus according to the present disclosure is configured to have the upper sensors and the lower sensors with respective light collection lenses, thereby enabling the light transmittance to be measured more accurately.

Besides, the substrate treatment apparatus according to the present disclosure is configured to allow the light transmittance at various points on a concentric circle of the blocking plate to be measured through the rotation of the substrate-holding unit.

Further, the substrate treatment apparatus according to the present disclosure is configured to allow the lower sensors to be located under the substrate-holding unit and to have the first light passing hole and the second light passing hole formed on the substrate-holding unit and the heating unit respectively in such a way as to allow the light irradiated from the light transmitter to pass therethrough, thereby performing the installation work of the lower sensors more easily.

Furthermore, the substrate treatment apparatus according to the present disclosure is configured to allow the first light passing hole formed on the substrate-holding unit to have the shape of arc including the positions of the lower sensors about the center of the substrate, so that in the state where the substrate-holding unit rotates by a given angle, the light transmittance at the different points on the concentric circle of the blocking plate is measurable.

Further, the substrate treatment apparatus according to the present disclosure is configured to allow the upper sensor and the lower sensor to reciprocate in a radial direction about a center of the substrate, and to allow to the first light passing hole and the second light passing hole to extend in the radial direction respectively, so that if the upper sensors and the lower sensors move by given distances from the center of the substrate in the radial direction of the substrate in the state where they are located at the corresponding positions to each other, the light transmittance of the blocking plate is measurable at different positions in the radial direction of the blocking plate.

The present disclosure may be modified in various ways and may have several exemplary embodiments. It is therefore intended that the scope of the disclosure be limited not by this detailed description, but rather by the claims appended hereto, and it should be understood that the disclosure covers all the modifications, equivalents, and replacements within the idea and technical scope of the disclosure.

What is claimed is:

1. A substrate treatment apparatus comprising:
a substrate-holding unit for holding and rotating a substrate;
a treatment liquid feed unit for feeding treatment liquid to a top or underside of the substrate held by the substrate-holding unit;
a heating unit located under the substrate to heat the substrate;
a blocking plate located on the substrate-holding unit above the heating unit in such a way as to allow light to pass therethrough toward the substrate and to prevent the treatment liquid from entering the heating unit;
an upper sensor located above the blocking plate to constitute one of a light transmitter and a light receiver; and
a lower sensor located under the blocking plate to constitute the other,
wherein a quantity of light irradiated from the light transmitter and thus reaching the light receiver is measured to allow the light transmittance of the blocking plate to be obtained.

2. The substrate treatment apparatus according to claim 1, wherein the upper sensor and the lower sensor are connected to light production and measurement devices through optical fibers, and the light production and measurement devices are connected to a controller.

3. The substrate treatment apparatus according to claim 1, wherein two or more sets of the upper sensor and the lower sensor are provided at different positions in a radial direction of the substrate about a center of the substrate.

4. The substrate treatment apparatus according to claim 1, wherein the upper sensor and the lower sensor have respective light collection lenses.

5. The substrate treatment apparatus according to claim 1, wherein a light source applied to the light transmitter is an LED or laser light.

6. The substrate treatment apparatus according to claim 1, wherein the light transmittance on at various points on a concentric circle, about a center of substrate, of the blocking plate can be measured through the rotation of the substrate-holding unit.

7. The substrate treatment apparatus according to claim 1, wherein the lower sensor is located under the substrate-holding unit, and the substrate-holding unit and the heating unit have first light passing hole and second light passing hole formed thereon to allow the light irradiated from the light transmitter to pass therethrough respectively.

8. The substrate treatment apparatus according to claim 7, wherein, in plan view, the first light passing hole formed on the substrate-holding unit extends in a circular direction about the center of the substrate to have a shape of arc and includs the position of the lower sensor.

9. The substrate treatment apparatus according to claim 7, wherein the upper sensor and the lower sensor reciprocate in a radial direction about a center of the substrate, and the first light passing hole and the second light passing hole extend in the radial direction respectively.

10. The substrate treatment apparatus according to claim 9, wherein the first light passing hole further extends in an circular direction about the center of the substrate so that the first light passing hole has crossing shape in the radial direction and circular direction.
